(19) United States
(12) Patent Application Publication
(10) Pub. No.: US 2026/0059825 A1
(43) Pub. Date: Feb. 26, 2026

(54) METHOD AND APPARATUS FOR FABRICATING SEMICONDUCTOR DEVICE

(71) Applicant: SEMES CO., LTD., Cheonan-si (KR)

(72) Inventors: Seung Jun OH, Cheonan-si (KR); CHENGYEH HSU, Cheonan-si (KR)

(73) Assignee: SEMES CO., LTD., Cheonan-si (KR)

(21) Appl. No.: 19/306,751

(22) Filed: Aug. 21, 2025

(30) Foreign Application Priority Data
Aug. 22, 2024 (KR) 10-2024-0112694

(51) Int. Cl. H01L 21/28; H01J 37/32; H10D 30/01

(52) U.S. Cl. CPC H01L 21/28185; H01J 37/32449; H01L 21/28194; H10D 30/0191; H01J 2237/332

(57) ABSTRACT

Proposed is a method for fabricating a semiconductor device. The method includes a semiconductor structure provision step of providing a semiconductor structure including one or more channel layers each having an interfacial layer formed on a surface thereof, an interfacial layer surface activation step for activating a surface of the interfacial layer by treating the semiconductor structure with hydrogen plasma, and a dipole doping step for bonding a dipole-forming atom to the activated surface of the interfacial layer. According to the method, a dipole interface can be formed in a gate insulating layer through a simple process by doping dipole-forming atoms after activating the interfacial layer surface by hydrogen plasma treatment.

### CROSS REFERENCE TO RELATED APPLICATION

The present application claims priority to Korean Patent Application No. 10-2024-0112694, filed Aug. 22, 2024, the entire contents of which are herein incorporated by reference for all purposes.

### BACKGROUND OF THE INVENTION

### Field of the Invention

The present disclosure relates to a method and apparatus for fabricating a semiconductor device.

### Description of the Related Art

With the application of high-k dielectrics and metal gate electrodes to gate stacks of semiconductor devices, technologies for controlling a transistor's threshold voltage (Vt) are becoming increasingly important. Known methods for controlling the threshold voltage of a transistor include adding a work function adjustment layer to a gate stack or doping a gate insulating layer with lanthanum (La), aluminum (Al), etc., to form a dipole.

A common conventional method for forming a dipole is to form a dipole-forming layer on a gate insulating layer and then perform a high-temperature heat treatment. At this time, the gate insulating layer is formed on a channel layer and often consists of a multi-layer stack, including an interfacial layer, commonly a silicon oxide film, and a high-k dielectric layer made of a hafnium oxide film (HfO2). The dipole-forming layer may be a lanthanum (La) or aluminum (Al) layer, or a layer containing lanthanum (La) or aluminum (Al). When high-temperature heat treatment is performed after creating the dipole-forming layer, lanthanum (La) or aluminum (Al) atoms of the dipole-forming layer are introduced into the gate insulating layer and are activated by high-temperature energy, leading to the formation of dipoles within the gate insulating layer. Generally, dipoles are formed at the interface between the interfacial layer and the high-k dielectric layer constituting the gate insulating layer, and thus a dipole interface is formed because of the creation of dipoles.

Meanwhile, in the above method, a capping layer is formed on top of the dipole-forming layer to prevent structural deformation due to high temperature and to promote diffusion of lanthanum (La) or aluminum (Al) atoms into the gate insulating layer, and then high-temperature heat treatment is performed. Titanium nitride (TiN) and/or amorphous silicon films are used as the capping layer. Since the capping layer is an unnecessary layer in the gate stack, the capping layer is removed by etching after the high-temperature heat treatment for forming the dipole interface.

As such, the conventional dipole interface formation technology requires a capping layer formation and removal process, making the process complex, and requires a high-temperature heat treatment process, which increases the thermal budget for a semiconductor device.

In particular, the conventional dipole interface formation technology is more difficult to apply to three-dimensional (3D) transistor structures, such as gate all around field effect transistor (GAA-FET), complementary field effect transistor (C-FET), and Forksheet structures. For example, in the case of a C-FET structure in which GAA-structured transistors are vertically stacked, because the gap between channel layers is very small, process difficulties arise in forming and removing a capping layer in the gap between the channel layers. These difficulties can be more serious when the channel layer is in the form of a nanosheet rather than a nanowire.

There is also a method of directly doping lanthanum (La) or aluminum (Al) into the gate insulating layer using implantation to form a dipole interface, but this method is not applicable to a three-dimensional transistor structure such as a C-FET because doping the entire gate insulating layer formed to surround the four sides of the channel layer is impossible.

### DESCRIPTION OF THE RELATED ART

(Patent Document 1) US Patent Application Publication No. 2022-0085015 A1 (May 17, 2022)
(Patent Document 2) US Patent Application Publication No. 2022-0238680 A1 (Jul. 28, 2022)

### SUMMARY OF THE INVENTION

Accordingly, the present disclosure has been made keeping in mind the above problems occurring in the related art, and an objective of the present disclosure is to provide a method and apparatus for fabricating a semiconductor device capable of forming a dipole interface in a gate insulating layer through a simpler process.

An objective of the present disclosure is to provide a method and apparatus for fabricating a semiconductor device capable of effectively forming a dipole interface in a gate insulating layer of a three-dimensional transistor structure.

An objective of the present disclosure is to provide a method and apparatus for fabricating a semiconductor device capable of forming a dipole interface in a gate insulating layer without damaging an interfacial layer.

A method for fabricating a semiconductor device according to the present disclosure includes: a semiconductor structure provision step of providing a semiconductor structure including one or more channel layers each having an interfacial layer formed on a surface thereof; an interfacial layer surface activation step for activating a surface of the interfacial layer by treating the semiconductor structure with hydrogen plasma; and a dipole doping step for bonding a dipole-forming atom to the activated surface of the interfacial layer.

In an embodiment of the present disclosure, the semiconductor structure may include: a substrate; and a plurality of channel layers arranged in a vertical direction (z-direction) on the substrate.

In an embodiment of the present disclosure, the plurality of channel layers may be provided in a form of nanosheets extending in a horizontal direction (x-direction).

In an embodiment of the present disclosure, the plurality of channel layers may be connected to each other by a source and a drain provided at respective ends in a horizontal direction (x-direction).

In an embodiment of the present disclosure, the interfacial layer may be a silicon oxide film.

In an embodiment of the present disclosure, a dangling bond may be formed on the interfacial layer surface through the interfacial layer surface activation step.

In an embodiment of the present disclosure, the interfacial layer surface activation step may be a step of treating the interfacial layer surface with hydrogen plasma using hydrogen radicals.

In an embodiment of the present disclosure, the dipole doping step may include: a dipole-forming precursor adsorption step in which a dipole-forming precursor containing a dipole-forming atom is adsorbed onto the surface of the interfacial layer; and a byproduct removal step for removing ligands of the dipole-forming precursor.

In an embodiment of the present disclosure, the dipole-forming atom may be lanthanum (La) or aluminum (Al).

In an embodiment of the present disclosure, the byproduct removal step may be a step of plasma treatment with a gas containing oxygen (O).

In an embodiment of the present disclosure, the dipole-forming precursor adsorption step and the byproduct removal step may be performed simultaneously, and even after the dipole-forming precursor adsorption step is completed, the byproduct removal step may be continuously performed for a predetermined period of time.

In an embodiment of the present disclosure, the interfacial layer surface activation step and the dipole doping step may be repeated two or more times.

A method for fabricating a semiconductor device according to the present disclosure includes: a semiconductor structure provision step of providing a semiconductor structure in which a plurality of channel layers is formed vertically spaced apart from each other on a substrate; an interfacial layer formation step of forming an interfacial layer by depositing a silicon oxide film on each of surfaces of the channel layers; an interfacial layer activation step in which the semiconductor structure is treated with hydrogen plasma to form a dangling bond on each surface of the interfacial layer; a dipole doping step for bonding a dipole-forming atom to the dangling bond on the surface of the interfacial layer by supplying a dipole-forming precursor containing the dipole-forming atom and oxygen gas while performing plasma treatment; a gate dielectric layer deposition step for depositing a gate dielectric layer on the interfacial layer surface where the dipole atom is bonded; and a gate metal layer deposition step.

In an embodiment of the present disclosure, the semiconductor structure provision step may include: a lamination step for alternately laminating a channel layer, which is a semiconductor layer, on a substrate, and a sacrificial layer that can be selectively etched with respect to the channel layer; a nanosheet pattern formation step of patterning the alternately laminated channel layer and sacrificial layer to a predetermined width; and an etching step for selectively etching the sacrificial layer in the nanosheet pattern.

In an embodiment of the present disclosure, the interfacial layer may be a silicon oxide film, and the gate dielectric layer may be a hafnium oxide film (HfO₂).

An apparatus for fabricating a semiconductor device according to the present disclosure includes: a chamber configured to provide a processing space thereinside; a susceptor positioned within the chamber to support a wafer; a plasma source configured to generate plasma in the processing space; a gas inlet configured to supply hydrogen gas, a dipole-forming precursor containing a dipole-forming atom, oxygen gas, and an inert gas into the chamber; an exhaust port configured to exhaust gas and byproducts inside the chamber; an ion blocker positioned above the susceptor to divide the processing space into an upper processing space and a lower processing space, and configured to include through holes connecting the upper processing space and the lower processing space; and a controller, wherein the controller may control to: place a wafer having a semiconductor structure formed thereon, with the semiconductor structure including one or more channel layers each having an interfacial layer deposited on a surface thereof, on the susceptor; generate hydrogen plasma by supplying the hydrogen gas and the inert gas to the processing space through the gas inlet to form a dangling bond on a surface of the interfacial layer; and generate plasma by supplying the dipole-forming precursor and the oxygen gas to the processing space through the gas inlet to bind a dipole-forming atom to the surface of the interfacial layer.

In an embodiment of the present disclosure, the ion blocker may be connected to ground by means of a switch, and the controller may control the switch to connect the ion blocker to the ground at least while hydrogen plasma is generated in the processing space.

In an embodiment of the present disclosure, the gas inlet may include a first gas inlet configured to supply gas to the upper processing space, and a second gas inlet configured to supply gas to the lower processing space, wherein the hydrogen gas, the oxygen gas, and the inert gas may be supplied to the upper processing space through the first gas inlet, and the dipole-forming precursor may be supplied to the lower processing space through the second gas inlet.

According to an embodiment of the present disclosure, a dipole interface can be formed in a gate insulating layer through a simple process by doping dipole-forming atoms onto a surface of an interfacial layer after activating the surface with hydrogen plasma treatment.

Furthermore, according to the present disclosure, since processes such as capping layer deposition and removal are unnecessary, a dipole interface can be effectively formed even in a gate insulating layer of a three-dimensional transistor structure with a very small gap between channel layers.

Furthermore, according to the present disclosure, a dipole interface can be formed in a gate insulating layer without damaging an interfacial layer by treating the interfacial layer surface with hydrogen plasma using hydrogen radicals.

### BRIEF DESCRIPTION OF THE DRAWINGS

FIG. 1 is a flowchart of a method for fabricating a semiconductor device according to an embodiment of the present disclosure.

FIG. 2 is a flowchart of a dipole doping method according to an embodiment of the present disclosure.

FIGS. 3A to 3G are views showing each step of a method for fabricating a semiconductor device according to an embodiment of the present disclosure.

FIG. 4 shows the XPS measurement results for the interfacial layer surface after hydrogen plasma treatment.

FIGS. 5A to 5D are views showing a method of manufacturing a semiconductor structure according to an embodiment of the present disclosure.

FIG. 6 is a schematic view of an apparatus for fabricating a semiconductor device according to the present disclosure.

### DETAILED DESCRIPTION OF THE INVENTION

Hereinafter, with reference to the accompanying drawings, embodiments of the present disclosure will be described in detail so that those skilled in the art may easily carry out the present disclosure. The present disclosure may be embodied in many different forms and is not limited to the embodiments set forth herein.

In order to clearly describe the present disclosure, parts irrelevant to the description are omitted, and the same reference numerals are assigned to the same or similar components throughout the specification.

In addition, in various embodiments, components having the same configuration will be described only in representative embodiments by using the same reference numerals, and in other embodiments, only configurations different from the representative embodiments will be described.

Throughout the specification, when a part is said to be “connected (or coupled)” to another part, this includes not only the case of being “directly connected (or coupled)” but also “indirectly connected (or coupled)” with another member in between. In addition, when a part “includes”, “has”, or “comprises” a certain part, this means that other components may be further included without excluding other components unless otherwise stated.

Unless otherwise defined, all terms used herein, including technical or scientific terms, have the same meaning as commonly understood by a person skilled in the art. Terms such as those defined in the commonly used dictionaries should be construed as having meanings consistent with the meanings in the context of the related art and shall not be construed as ideal or excessively formal meanings unless expressly defined in this application.

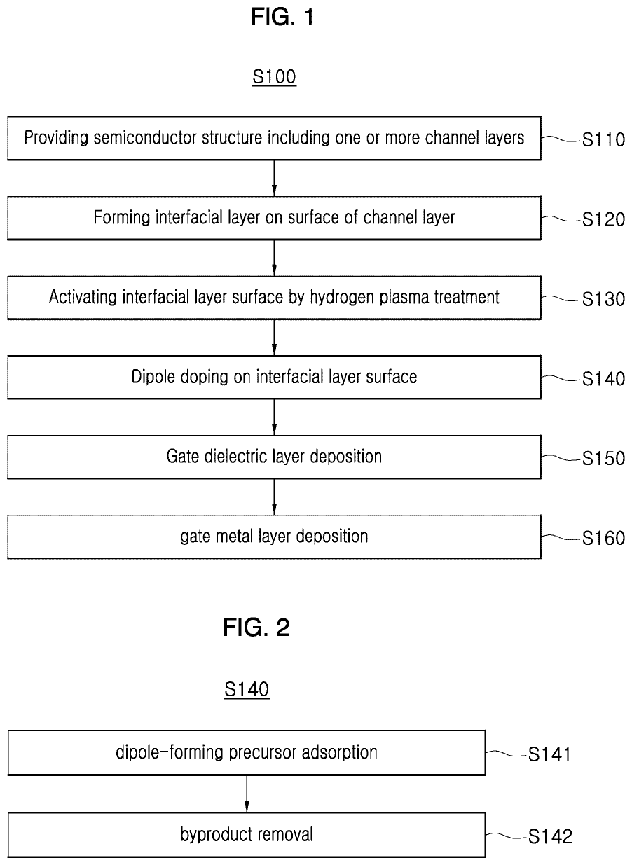

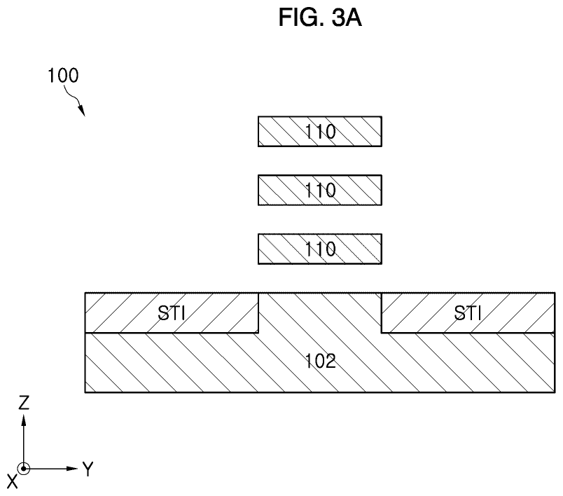

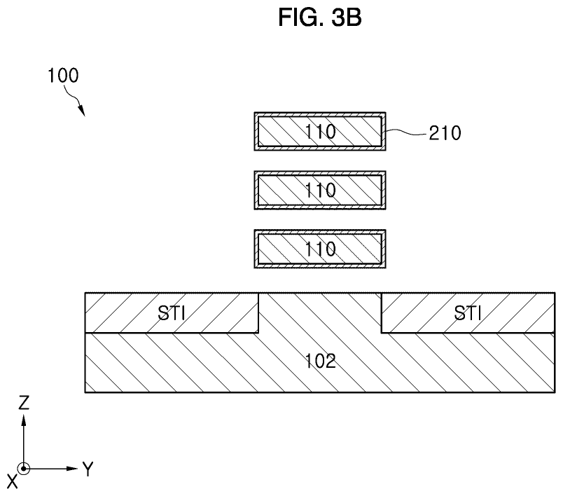

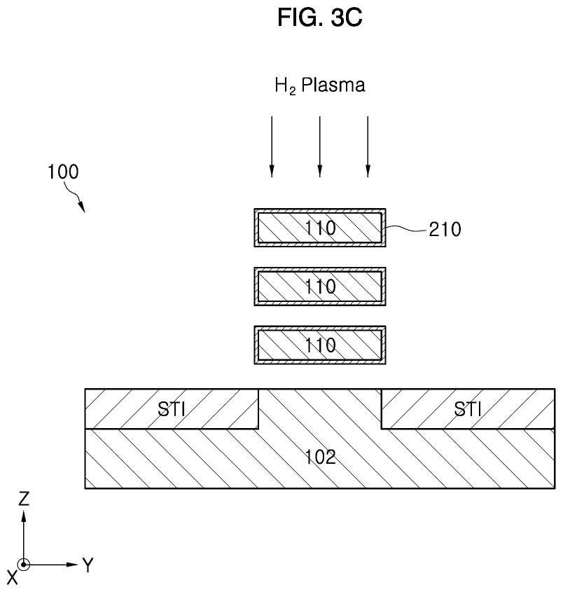

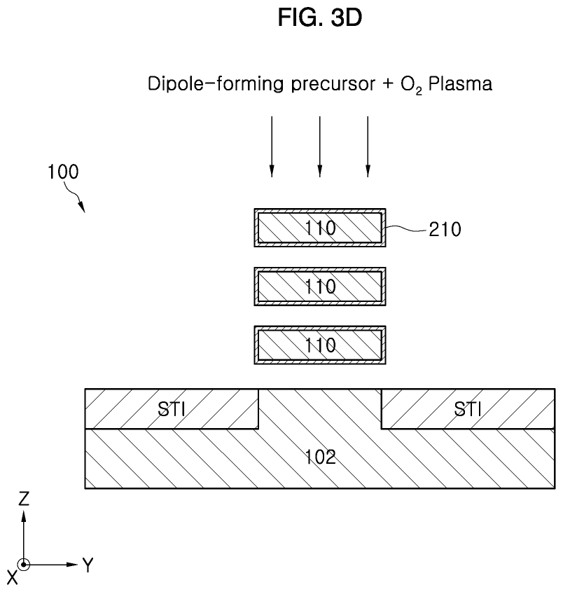

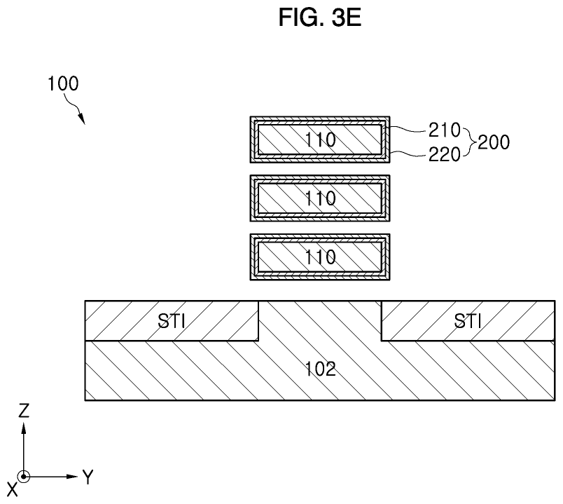

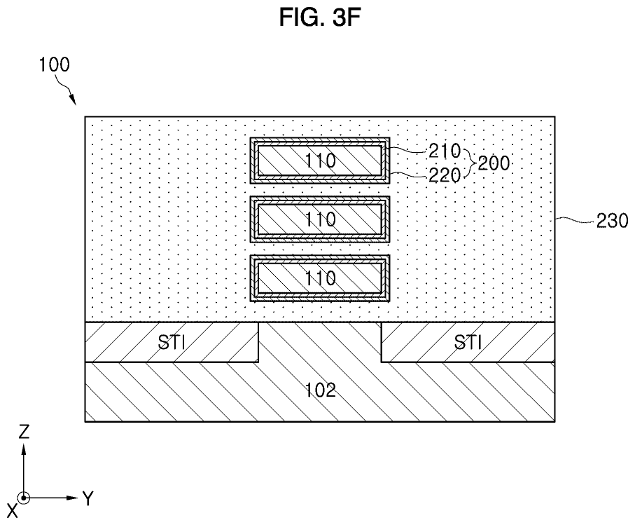

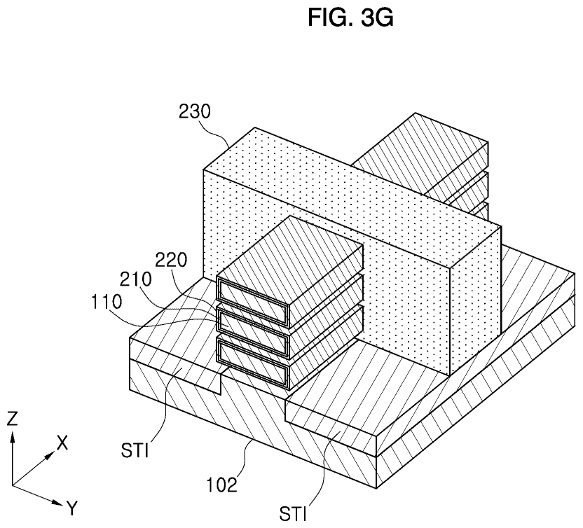

FIG. 1 is a flowchart of a method for fabricating a semiconductor device according to an embodiment of the present disclosure, FIG. 2 is a flowchart of a dipole doping method according to an embodiment of the present disclosure, and FIGS. 3A to 3G are views showing each step of a method for fabricating a semiconductor device according to an embodiment of the present disclosure. Hereinafter, a method for fabricating a semiconductor device according to an embodiment of the present disclosure will be described with reference to FIGS. 1 to 3G. Since FIGS. 1 to 3G are drawings to help understand the method for fabricating a semiconductor device according to an embodiment of the present disclosure, they only schematically show the main steps, and it should be understood that there may be additional steps and structures that are not described.

As shown in the flowchart in FIG. 1, a method (S100) for fabricating a semiconductor device according to an embodiment of the present disclosure may include: a semiconductor structure provision step (S110) of providing a semiconductor structure including one or more channel layers; an interfacial layer formation step (S120) of forming an interfacial layer on the surface of the channel layer; an interfacial layer surface activation step (S130) of activating the interfacial layer surface by treating the semiconductor structure with hydrogen plasma; a dipole doping step (S140) for bonding dipole-forming atoms to the activated interfacial layer surface; a gate dielectric layer deposition step (S150) for forming a gate dielectric layer on the interfacial layer surface to which the dipole-forming atoms are bonded; and a gate metal layer deposition step (S160).

The semiconductor structure provided in the semiconductor structure provision step (S110) is a semiconductor structure including one or more channel layers.

As exemplarily shown in FIG. 3A, a semiconductor structure 100 provided in the semiconductor structure provision step (S110) includes a substrate 102 and one or more channel layers 110 formed on the substrate 102.

The substrate 102 may be, but is not limited to, a single crystal silicon (Si) substrate. The substrate 102 may be a silicon germanium (SiGe), silicon carbide (Sic), carbon-doped silicon (Si:C), silicon germanium carbide (SiGeC), carbon-doped silicon germanium (SiGe:C), a III-V group or II-VI group compound semiconductor, a silicon-on-insulator (SOI), a SiGe-on-insulator, glass, sapphire, an organic semiconductor substrate, or a substrate including these materials. The substrate 102 may include doped or undoped regions and may include patterned or unpatterned regions. As shown in FIG. 3A, the substrate 102 may include an isolation region, for example, a shallow trench isolation (STI) region.

The channel layer 110 may be a semiconductor layer. The channel layer 110 may be a silicon layer or a silicon germanium (SiGe) layer. The channel layer 110 may be a single crystal layer. The channel layer 110 may be a charge transfer path between the e source and drain terminals in a transistor having a three-dimensional structure such as a GAA structure, a C-FET structure, or a Forksheet structure.

The channel layer 110 may be formed in a nanosheet shape that extends long in the x-direction of FIG. 3A. That is, the channel layer 110 may be formed in a sheet shape with a rectangular cross-section.

Although FIG. 3A shows that three channel layers 110 are formed in the z-direction on the substrate 102, this is exemplary, and the number of channel layers 110 in the present disclosure is not limited to a specific value or range.

Although FIG. 3A shows that the channel layers 110 are arranged only in the z-direction, another plurality of channel layers 110 spaced apart in the x-direction and/or y-direction may be included.

The channel layers 110 may be supported on the substrate 102 by a separate configuration not shown in FIG. 3A. For example, a source and a drain connecting the channel layers 110 may be provided at opposite ends of the channel layers 110 in the x-direction to connect the channel layers 110 to each other. That is, the channel layers 110 may be connected to the source and the drain at opposite ends, and may be in the form of a bridge supported by the source and the drain.

The interfacial layer formation step (S120) is a step of forming an interfacial layer 210 that constitutes a gate insulating layer 200 together with a gate dielectric layer 220 described later, on the surface of the channel layer 110. The interfacial layer 210 may be a silicon oxide layer and may be formed to a thickness of several to several tens of Å. The interfacial layer 210 may be formed by atomic layer deposition so as to be formed to a uniform thickness over the entire area of the channel layer 110, but is not limited thereto.

As shown in FIG. 3B, the interfacial layer 210 having a uniform thickness may be formed on the surface of each channel layer 110 through the interfacial layer forming step (S120). When the channel layer 110 has a nanosheet shape extending in the x-direction, the interfacial layer 210 may be formed to surround the upper surface (+z direction), lower surface (−z direction), left surface (−y direction), and right surface (+y direction) of each nanosheet.

The interfacial layer surface activation step (S130) is a step of activating the interfacial layer 210 surface by treating the semiconductor structure, in which the interfacial layer 210 is formed on the surface of the channel layer 110, with hydrogen plasma (FIG. 3C). In this case, surface activation means that a dangling bond is formed on the surface.

For hydrogen plasma treatment, plasma may be generated by supplying hydrogen gas and an inert gas. Hydrogen plasma and the interfacial layer 210 may react to form a dangling bond on the surface of the interfacial layer 210. When the interfacial layer is a silicon oxide layer, oxygen on the surface of the silicon oxide layer may be at least partially removed by the hydrogen plasma. The oxygen on the surface of the interfacial layer 210 may react with the hydrogen in the hydrogen plasma and be removed as water (H2O) molecules. As a result, the surface of the interfacial layer 210 becomes an oxygen-deficient silicon oxide (SiOx, x<2) film, and a large number of dangling bonds may be formed on the surface of the interfacial layer 210.

The hydrogen plasma treatment may be performed in an atmosphere at a pressure of 10 mtorr to 1 torr and a temperature of 300° C. to 700° C.

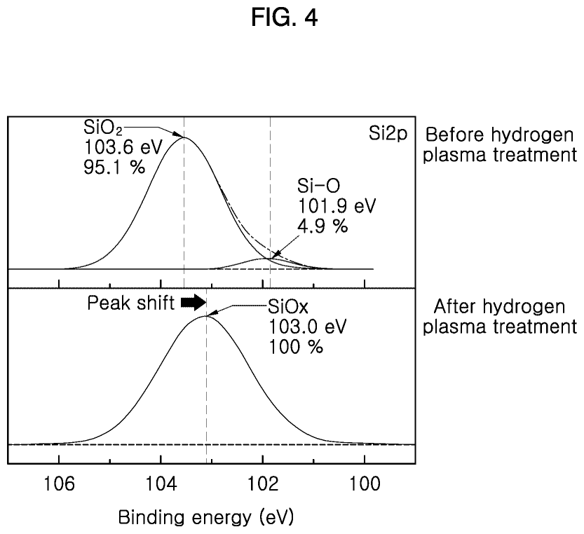

FIG. 4 shows the XPS measurement results for the interfacial layer surface after hydrogen plasma treatment. As confirmed in FIG. 4, before hydrogen plasma treatment, SiO2 is mostly measured, but after hydrogen plasma treatment, SiOx with a binding energy of 103.0 eV is measured. That is, oxygen is removed from the interfacial layer surface by hydrogen plasma treatment to form SiOx, which means that dangling bonds are formed at the sites where oxygen atoms are removed. Since dangling bonds are in a state of being easily bonded, the interfacial layer becomes activated as a result of hydrogen plasma treatment.

The interfacial layer surface activation step (S130) may be performed mainly using hydrogen radicals, excluding hydrogen ions in the hydrogen plasma. For this purpose, any appropriate means, such as an ion blocker for blocking ions and a remote plasma source for supplying only radicals, may be used. By activating the interfacial layer surface using only hydrogen radicals, damage to the interfacial layer caused by ions or generation of fixed charges may be suppressed, and a dipole interface may be formed in the gate insulating layer.

Referring back to FIG. 1, the dipole doping step (S140) is performed to bind dipole-forming atoms to the activated interfacial layer 210 surface. The dipole-forming atoms may be lanthanum (La) or aluminum (Al), and an atom suitable for obtaining a desired threshold voltage (Vt) may be selected. The dipole-forming atoms may be bonded to the dangling bonds on the surface of the interfacial layer 210 created in the interfacial layer surface activation step (S130) by the dipole doping step (S140).

Referring to FIGS. 2 and 3D, the dipole doping step (S140) may include a dipole-forming precursor adsorption step (S141) and a byproduct removal step (S142).

The dipole-forming precursor adsorption step (S141) is a step in which a dipole-forming precursor containing dipole-forming atoms is adsorbed onto the surface of the interfacial layer 210. To be specific, dipole-forming atoms, such as lanthanum (La) or aluminum (Al), included in the dipole-forming precursor are adsorbed onto dangling bonds formed on the surface of the interfacial layer 210.

The dipole-forming precursor may be a compound having ligands bonded to a dipole-forming atom, such as lanthanum (La) or aluminum (Al). Without being particularly limited, the dipole-forming precursor may be AlH₃ (NEtMe₂), AlH₃ (MeNC₄H₄), AlMe₂ (OiPr), AlMe₃, La(Cp^{Et})₃, La(Cp^{iPr})₃, etc.

The byproduct removal step (S142) is a step for removing the ligands of the dipole-forming precursor, and may be a step of treating with plasma of a gas capable of removing the ligands. The gas capable of removing the ligands may be a gas containing oxygen (O). For example, it may be oxygen (O₂), ozone (O₃), carbon dioxide (CO₂), or nitrous oxide (N₂O), and oxygen (O₂) gas is desirable. The ligands of the dipole-forming precursor are removed by the oxygen plasma treatment, and only dipole-forming atoms such as lanthanum (La) and aluminum (Al) may be bonded to the dangling bonds on the surface of the interfacial layer 210.

According to an embodiment of the present disclosure, since the surface of the interfacial layer 210 is activated by hydrogen plasma treatment, dipole-forming atoms may be combined on the surface of the interfacial layer to form a dipole interface without a separate high-temperature heat treatment process. In addition, since dipole doping is performed directly on the surface of the interfacial layer before depositing the gate dielectric layer, high-temperature heat treatment for diffusion is unnecessary, and the capping layer formation and removal process required for high-temperature heat treatment is also unnecessary.

Although in FIG. 2, the dipole-forming precursor adsorption step (S141) and the byproduct removal step (S142) are shown to be performed sequentially, the two steps may be performed simultaneously. That is, the dipole doping step (S140) may be performed by supplying a dipole-forming precursor and oxygen plasma together. The ligands of the dipole-forming precursor are removed by the oxygen plasma, and only the dipole-forming atoms may be bonded to the dangling bonds on the surface of the interfacial layer 210.

When the dipole-forming precursor adsorption step (S141) and the byproduct removal step (S142) are performed simultaneously, the byproduct removal step (S142) may continue for a certain period of time even after the dipole-forming precursor adsorption step (S141) is completed. That is, dipole doping is performed by supplying the dipole-forming precursor and oxygen plasma together, and then the supply of the dipole-forming precursor is stopped and the oxygen plasma treatment may be continued for a certain period of time. Due to this, the ligands on the surface of the interfacial layer 210 or inside the treatment space may be completely removed.

The interfacial layer surface activation step (S130) and the dipole doping step (S140) may be repeated more than twice. That is, a unit cycle including the interfacial layer surface activation step (S130) and the dipole doping step (S140) may be repeated multiple times. According to this method, after the dangling bonds formed on the surface of the interfacial layer 210 by the hydrogen plasma treatment are consumed in the dipole doping step, the hydrogen plasma treatment is repeated again to newly create dangling bonds on the surface of the interfacial layer 210, thereby providing a new site for the dipole-forming atomic bond.

After the dipole doping step (S140), the gate dielectric layer deposition step (S150) may be performed. As shown in FIG. 3E, the gate dielectric layer 220 may be deposited to surround the entire area of the interfacial layer 210. The gate dielectric layer 220 may constitute the gate insulating layer 200 together with the interfacial layer 210. Since dipole doping is performed on the surface of the interfacial layer 210, the gate insulating layer 200 may include a dipole interface.

The gate dielectric layer 220 may be formed as a high-k dielectric layer including a high-k material. The gate dielectric layer 220 may include, for example, a hafnium oxide film (HfO₂), a zirconium oxide film (ZrO₂), an yttrium oxide film (Y₂O₃), an aluminum oxide film (Al₂ O₃), or a ternary oxide film such as HfZro, HfLaOx, or HfTiO. Preferably, the gate dielectric layer 220 may be a hafnium oxide film (HfO₂).

The gate dielectric layer 220 may be deposited by atomic layer deposition (ALD) to surround the entire area of the interfacial layer 210 with a uniform thickness.

After the gate dielectric layer 220 is deposited, a gate metal layer deposition step (S160) may be performed. As shown in FIGS. 3F and 3G, a gate metal layer 230 may be formed as a pillar structure extending in the y-direction that surrounds all of the channel layers 110. The gate metal layer 230 may function as a gate electrode for applying a gate voltage to turn the transistor on and off.

The gate metal layer 230 may include metals such as titanium nitride (TiN), tantalum nitride (TaN), tantalum carbide (TaC), cobalt (Co), ruthenium (Ru), aluminum (Al), or combinations thereof. The gate metal layer 230 may be a single layer or may be formed as multiple layers.

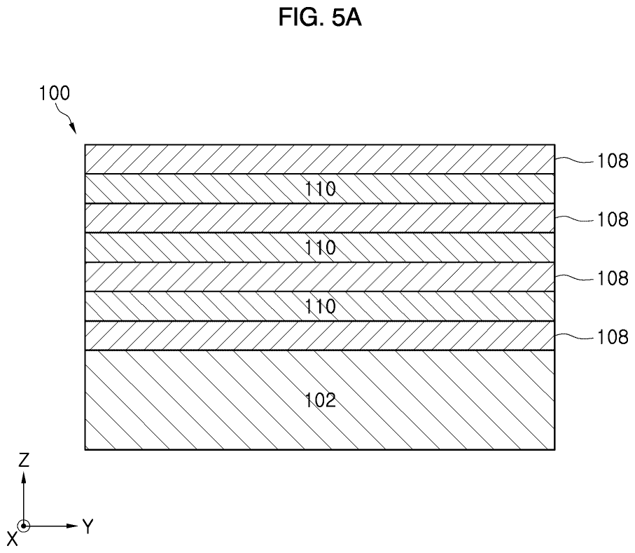

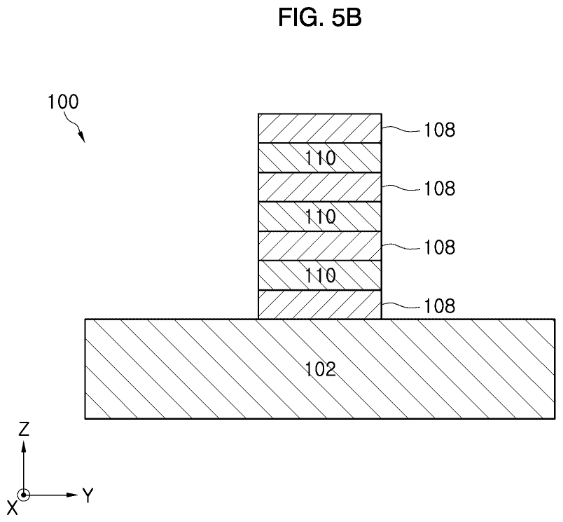

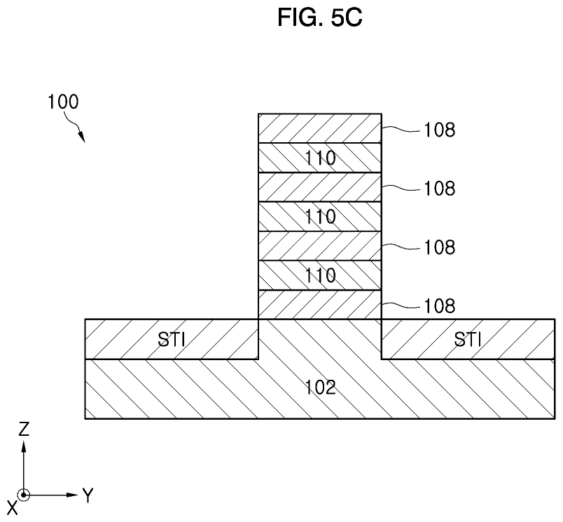

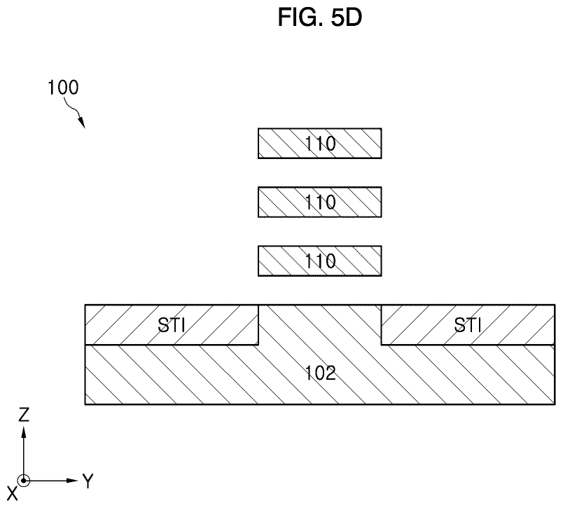

FIGS. 5A to 5D are views showing an exemplary method of manufacturing a semiconductor structure of FIG. 3A. Because FIGS. 5A to 5D are views to help understand the method of forming a channel layer 110, only the main steps are schematically depicted, and it should be understood that there may be additional steps and structures that are not described.

As shown in FIG. 5A, a sacrificial layer 108 and the channel layer 110 are alternately deposited on a substrate 102. The sacrificial layer 108 is made of a material that may be selectively etched with respect to the channel layer 110. The etching selectivity of the sacrificial layer 108 with respect to the channel layer 110 may be 10:1 or more.

When the channel layer 110 is a silicon layer, the sacrificial layer 108 may be a silicon germanium (SiGe) layer. When the channel layer 110 is a silicon germanium (SiGe) layer, the sacrificial layer 108 may be a germanium (Ge) layer. Alternatively, the channel layer 110 and the sacrificial layer 108 may be silicon germanium layers having different germanium (Ge) concentrations. For example, the channel layer 110 may be a SiGeₓ layer having a germanium content of x with respect to silicon, and the sacrificial layer 108 may be a SiGe_{y} layer having a germanium content of y with respect to silicon.

As shown in FIG. 5B, the sacrificial layer 108 and the channel layer 110 are patterned to have a nanosheet shape with a predetermined width in the y-direction. Any appropriate masking material and anisotropic etching method may be used for patterning.

After patterning, an isolation region, for example, an STI region, may be formed in a predetermined region of the substrate 102 as shown in FIG. 5C.

The sacrificial layer 108 may be selectively removed as in FIG. 5D. The semiconductor structure of FIG. 3A may be provided by selectively removing the sacrificial layer 108. The sacrificial layer 108 may be removed by any appropriate etching method that can selectively etch the sacrificial layer 108 with respect to the channel layer 110. Atomic layer etching (ALE) may be used for etching the sacrificial layer 108.

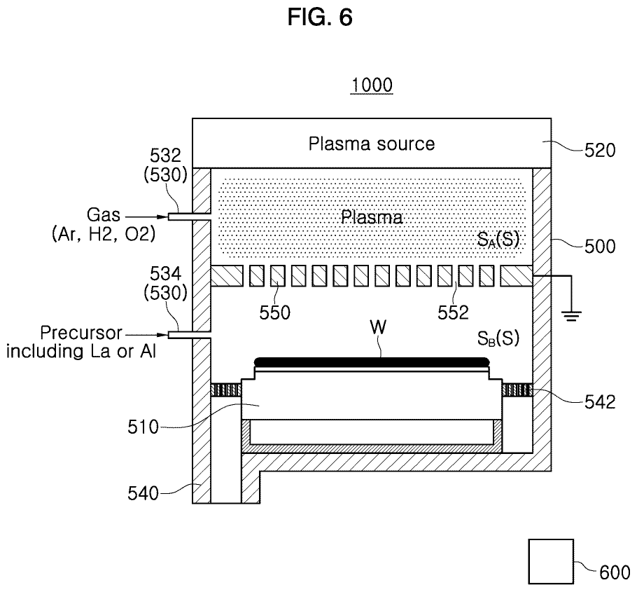

FIG. 6 is a schematic view of an apparatus for fabricating a semiconductor device according to the present disclosure. The apparatus for fabricating a semiconductor device in FIG. 6 is an apparatus suitable for performing steps S130 and S140 of the method for fabricating a semiconductor device (FIG. 1) according to an embodiment of the present disclosure.

Referring to FIG. 6, an apparatus 1000 for fabricating a semiconductor device according to an embodiment of the present disclosure may include: a chamber 500; a susceptor 510 positioned within the chamber to support a wafer W; a plasma source 520 for generating plasma; a gas inlet 530 for supplying gas into the chamber; an exhaust port 540 for exhausting gas and byproducts inside the chamber; an ion blocker 550 placed above the susceptor 510; and a controller 600.

The chamber 500 may provide a processing space S in which the method for fabricating a semiconductor device is performed, and may be made of a metal such as aluminum (Al). The processing space S may include an upper processing space S_{A} and a lower processing space S_{B} based on the ion blocker 550.

The susceptor 510 supports the wafer W within a processing space S, specifically, the lower processing space S_{B}. The wafer W may be supplied to the lower processing space S_{B} with the semiconductor structure of FIG. 3B formed thereon. That is, the wafer W on which, the semiconductor structure forming process of FIG. 5 and the interfacial layer 210 forming process of FIG. 3B are performed outside the apparatus 1000 for fabricating a semiconductor device, may be supplied to the lower processing space S_{B} and placed on the susceptor 510. A heater (not shown) for heating the wafer W may be built into the susceptor 510.

The plasma source 520 is configured to generate plasma in the processing space S, specifically, the upper processing space S_{A}, and any plasma source can be used. The plasma source 520 may be any one of a microwave source, an inductively coupled plasma (ICP) source, a capacitively coupled plasma (CCP) source, and a remote plasma source.

The gas inlet 530 may include: a first gas inlet 532 for supplying an inert gas such as hydrogen (H₂), oxygen (O₂), and argon (Ar); and a second gas inlet 534 for supplying a dipole-forming precursor. The first gas inlet 532 may be provided to supply gas to the upper processing space S_{A}, which is a processing space above the ion blocker 550, and the second gas inlet 534 may be provided to supply gas to the lower processing space S_{B} below the ion blocker 550.

The exhaust port 540 is provided at the bottom of the chamber 500 to exhaust gas and byproducts inside the chamber. For this purpose, the exhaust port 540 may be connected to a vacuum pump (not shown). A baffle plate 542 may be placed between the processing space S and the exhaust port 540 to control exhaust conductance. The baffle plate 542 may be placed between the side wall of the chamber 500 and the susceptor 510.

The ion blocker 550 divides the processing space S inside the chamber into the upper processing space S_{A} and the lower processing space S_{B}, and may be provided in the form of a plate including a plurality of through holes 552. The upper processing space S_{A} and the lower processing space S_{B} may be connected through the plurality of through holes 552. The ion blocker 550 may be connected to the ground by means of a switch that is not shown in the drawing. When the ion blocker 550 is connected to the ground, ions of the plasma generated in the upper processing space S_{A} are blocked by the ion blocker 550, and only electrically neutral radicals can be supplied to the lower processing space S_{B} where the wafer W is placed through the through holes 552. If it is unnecessary to block the ions, the ion blocker 550 may be switched so as to be not connected to the ground.

The controller 600 controls the operation of the apparatus 1000 for fabricating a semiconductor device so that the method for fabricating a semiconductor device according to an embodiment of the present disclosure may be performed. The controller 600 may be configured to include a CPU, memory, and circuits. The CPU may be any form of general-purpose processor, and the memory may be any form of local or remote digital storage including RAM, ROM, a floppy disk, a hard disk, etc. The memory may store a process recipe for performing the method for fabricating a semiconductor device according to an embodiment of the present disclosure.

The controller 600 may control the plasma source 520 to generate hydrogen plasma while supplying hydrogen (H₂) gas and inert gas to the upper processing space S_{A} through the first gas inlet 532 when the wafer W is placed on the susceptor 510. The surface of the interfacial layer 210 may be activated by hydrogen plasma. At this time, the controller 600 may control switching so that the ion blocker 550 is connected to the ground, thereby blocking the ions of the plasma and allowing only hydrogen radicals to be supplied to the wafer W through the through holes 552. By activating the surface of the interfacial layer by hydrogen radicals, a dipole interface may be formed in the gate insulating layer without damaging the interfacial layer.

After the interfacial layer surface activation step, the controller 600 may control the dipole doping step to be performed by supplying oxygen (O₂) gas to the upper processing space S_{A} through the first gas inlet 532 and supplying a dipole-forming precursor to the lower processing space S_{B} through the second gas inlet 534. The controller 600 may control the plasma source so that oxygen plasma is generated in the upper processing space S_{A}. As the ligands of the dipole-forming precursor and byproducts are removed by the oxygen plasma, dipole-forming atoms may be bonded to the surface of the interfacial layer 210. At this time, the controller 600 may selectively control the switching of the ion blocker 550 to be connected or not connected to the ground, thereby allowing the by-product removal to be done mainly by oxygen radicals or allowing oxygen ions to also participate in the by-product removal process.

The controller 600 may control the oxygen supply through the first gas inlet 532 to continue for a certain period of time even after the supply of the dipole-forming precursor through the second gas inlet 534 is stopped.

In addition, the controller 600 may control the apparatus 1000 for fabricating a semiconductor device so that the interfacial layer surface activation step and the dipole doping step are repeated two or more times. As a result, a unit cycle including the interfacial layer surface activation step and the dipole doping step may be repeated multiple times.

In the apparatus 1000 for fabricating a semiconductor device according to an embodiment of the present disclosure, the ion blocker 550 may be omitted. That is, in the case of a device that does not need to use only hydrogen radicals for interfacial layer activation, the ion blocker 550 may not be included in the apparatus 1000 for fabricating a semiconductor device. In this case, the processing space S is not divided into the upper processing space S_{A} and the lower processing space S_{B}.

Although in FIG. 6, the gas inlet 530 is shown as being provided on the side wall of the chamber 500, the present disclosure is not limited thereto. The gas inlet 530 may be provided to supply gas from the upper wall of the chamber 500 to the processing space S.

The present embodiments and drawings attached to this specification only clearly illustrate a part of the technical idea included in the present disclosure, and it is obvious that all modifications and specific embodiments that can be easily inferred by those skilled in the art within the scope of the technical idea included in the specification and drawings of the present disclosure are included in the scope of the rights of the present disclosure.

Therefore, the idea of the present disclosure should not be limited to the described embodiments, and not only the patent claims described below, but also all things that are equivalent or have equivalent modifications to these patent claims are considered to fall within the scope of the present disclosure.

What is claimed is:

1. A method for fabricating a semiconductor device, the method comprising:
a semiconductor structure provision step of providing a semiconductor structure including a plurality of channel layers and an interfacial layer formed on a surface of each channel layer of the plurality of channel layers;
an interfacial layer surface activation step for activating a surface of the interfacial layer by treating the semiconductor structure with hydrogen plasma; and
a dipole doping step for bonding a dipole-forming atom to the activated surface of the interfacial layer.

2. The method of claim 1,
wherein the semiconductor structure comprises:
a substrate, and
wherein the plurality of channel layers are arranged on the substrate in a vertical direction perpendicular to an upper surface of the substrate.

3. The method of claim 2, wherein the plurality of channel layers are provided in a form of nanosheets extending in a horizontal direction parallel to the upper surface of the substrate.

4. The method of claim 2, wherein the plurality of channel layers are connected to each other by a source and a drain provided at respective ends in a horizontal direction parallel to the upper surface of the substrate.

5. The method of claim 1,
wherein the interfacial layer is a silicon oxide film.

6. The method of claim 5,
wherein a dangling bond is formed on the surface of the interfacial layer through the interfacial layer surface activation step.

7. The method of claim 6,
wherein the interfacial layer surface activation step is a step of treating the surface of the interfacial layer with hydrogen plasma using hydrogen radicals.

8. The method of claim 1, wherein the dipole doping step comprises:
a dipole-forming precursor adsorption step in which a dipole-forming precursor containing the dipole-forming atom is adsorbed onto the surface of the interfacial layer; and
a byproduct removal step for removing ligands of the dipole-forming precursor.

9. The method of claim 8,
wherein the dipole-forming atom is lanthanum (La) or aluminum (Al).

10. The method of claim 8,
wherein the byproduct removal step is a plasma treatment step.

11. The method of claim 10,
wherein the byproduct removal step is a step of plasma treatment with a gas containing oxygen (O).

12. The method of claim 8,
wherein the dipole-forming precursor adsorption step and the byproduct removal step are performed simultaneously.

13. The method of claim 12,
wherein after the dipole-forming precursor adsorption step is completed, the byproduct removal step is continuously performed for a predetermined period of time.

14. The method of claim 1,
wherein the interfacial layer surface activation step and the dipole doping step are repeated two or more times.

15. A method for fabricating a semiconductor device, the method comprising:
a semiconductor structure provision step of providing a semiconductor structure in which a plurality of channel layers are formed vertically spaced apart from each other on a substrate;
an interfacial layer formation step of forming an interfacial layer by depositing a silicon oxide film on a surface of each channel layer of the plurality of channel layers;
an interfacial layer activation step in which the semiconductor structure is treated with hydrogen plasma to form a dangling bond on a surface of the interfacial layer;
a dipole doping step for bonding a dipole-forming atom to the dangling bond on the surface of the interfacial layer by supplying a dipole-forming precursor containing the dipole-forming atom and oxygen gas while performing plasma treatment;
a gate dielectric layer deposition step for depositing a gate dielectric layer on the surface of the interfacial layer where the dipole-forming atom is bonded; and
a gate metal layer deposition step.

16. The method of claim 15,
wherein the semiconductor structure provision step comprises:
a lamination step for alternately laminating each channel layer of the plurality of channel layers and each sacrificial layer of a plurality of sacrificial layers on the substrate to form a laminated structure,
wherein each channel layer is a semiconductor layer, and
wherein the plurality of sacrificial layers are selectively etched with respect to the plurality of channel layers;
a nanosheet pattern formation step of patterning the laminated structure to form a patterned laminated structure having a predetermined width; and
an etching step for selectively etching the plurality of sacrificial layers in the patterned laminated structure.

17. The method of claim 15,
wherein the interfacial layer is a silicon oxide film, and the gate dielectric layer is a hafnium oxide film (HfO₂).

18. An apparatus for fabricating a semiconductor device, the apparatus comprising:
a chamber configured to provide a processing space thereinside;
a susceptor positioned within the chamber to support a wafer;
a plasma source configured to generate plasma in the processing space;
a gas inlet configured to supply hydrogen gas, a dipole-forming precursor containing a dipole-forming atom, oxygen gas, and an inert gas into the chamber;
an exhaust port configured to exhaust gas and byproducts inside the chamber;
an ion blocker positioned above the susceptor to divide the processing space into an upper processing space and a lower processing space, and configured to include through holes connecting the upper processing space and the lower processing space; and
a controller,
wherein the controller controls to:
place a wafer having a semiconductor structure formed thereon, with the semiconductor structure including one or more channel layers each having an interfacial layer deposited on a surface of the interfacial layer, on the susceptor;
generate hydrogen plasma by supplying the hydrogen gas and the inert gas to the processing space through the gas inlet to form a dangling bond on a surface of the interfacial layer; and
generate plasma by supplying the dipole-forming precursor and the oxygen gas to the processing space through the gas inlet to bind a dipole-forming atom to the surface of the interfacial layer.

19. The apparatus of claim 18,
wherein the ion blocker is connected to ground by means of a switch, and
wherein the controller controls the switch to connect the ion blocker to the ground at least while hydrogen plasma is generated in the processing space.

20. The apparatus of claim 18,
wherein the gas inlet comprises a first gas inlet configured to supply gas to the upper processing space, and a second gas inlet configured to supply gas to the lower processing space,
wherein the hydrogen gas, the oxygen gas, and the inert gas are supplied to the upper processing space through the first gas inlet, and
wherein the dipole-forming precursor is supplied to the lower processing space through the second gas inlet.
